(19) United States
(12) Patent Application Publication
(10) Pub. No.: US 2011/0233661 A1
(43) Pub. Date: Sep. 29, 2011

(54) SEMICONDUCTOR MEMORY DEVICE WITH FIN

(75) Inventor: Takeshi Kajiyama, Yokohama-shi (JP)

(73) Assignee: KABUSHIKI KAISHA TOSHIBA, Tokyo (JP)

(21) Appl. No.: 13/051,846

(22) Filed: Mar. 18, 2011

(30) Foreign Application Priority Data
Mar. 23, 2010 (JP) 2010-066947

(51) Int. Cl. H01L 29/78; H01L 21/3205

(52) U.S. Cl. 257/330; 438/589; 257/E29.262; 257/E21.19

(57) ABSTRACT

According to one embodiment, a semiconductor memory device includes a fin-shaped active area, a gate electrode, a silicide layer, and a contact. The fin-shaped active area is provided in a semiconductor substrate and has a first side, a second side parallel to the first side, and a top face connecting the first and second sides. The gate electrode is formed in a trench formed in the active area such that it crosses the trench and is a part of a word line insulated from the active area. The silicide layer is located in the active area on either side of the gate electrode and is formed at least on the first side of the active area serving as a source and a drain region. The contact is connected to the silicide layer and connects at least a storage element.

### CROSS-REFERENCE TO RELATED APPLICATIONS

This application is based upon and claims the benefit of priority from Japanese Patent Application No. 2010-066947, filed Mar. 23, 2010; the entire contents of which are incorporated herein by reference.

### FIELD

Embodiments described herein relate generally to a semiconductor memory device applied to a memory cell transistor, such as an MRAM.

### BACKGROUND

Semiconductor memory devices, such as a DRAM, continue to shrink and the practical gate length decreases, which causes the problem of allowing a leakage current to flow even if the transistor is off.

To overcome this problem, a saddle-fin transistor has been developed. The saddle-fin transistor, which has an increased practical gate length L of the transistor, is useful in decreasing the off leakage. However, with the shrinkage of elements, the thickness of the active area of a saddle-fin trench has decreased. Therefore, the region of the top face of the active area becomes smaller and therefore the region where the active area contacts to a contact decreases, causing the problem of increasing the contact resistance.

### BRIEF DESCRIPTION OF THE DRAWINGS

FIG. 1 is a plan view of a semiconductor memory device according to a first embodiment;

FIG. 2 is a sectional view taken along line II-II of FIG. 1;

FIG. 3 is a sectional view taken along line III-III of FIG. 1;

FIG. 4 is a sectional view taken along line IV-IV of FIG. 1;

FIG. 5 is a perspective view of a part of FIG. 1;

FIG. 6 is a sectional view of a storage element;

FIG. 7 is a sectional view to explain a manufacturing method according to the first embodiment;

FIG. 8 is a sectional view to explain a manufacturing process following FIG. 7;

FIG. 9 is a sectional view to explain a manufacturing process following FIG. 8;

FIG. 10 is a sectional view to explain a manufacturing process following FIG. 9;

FIG. 11 is a sectional view to explain a manufacturing process following FIG. 10;

FIG. 12 is a sectional view to explain a manufacturing process following FIG. 11;

FIG. 13 is a sectional view to explain a manufacturing process following FIG. 12;

FIG. 14 is a sectional view to explain a manufacturing process following FIG. 13;

FIG. 15 is a sectional view to explain a modification of the first embodiment;

FIG. 16 is a plan view of a second embodiment;

FIG. 17 is a sectional view taken along line XVII-XVII of FIG. 16;

FIG. 18 is a sectional view to explain a manufacturing process following FIG. 17;

FIG. 19 is a sectional view of a modification of the second embodiment;

FIG. 20 is a plan view of a third embodiment; and

FIG. 21 is a plan view of a modification of the third embodiment.

### DETAILED DESCRIPTION

In general, according to one embodiment, a semiconductor memory device includes a fin-shaped active area, a gate electrode, a silicide layer, and a contact. The fin-shaped active area is provided in a semiconductor substrate and has a first side, a second side parallel to the first side, and a top face connecting the first and second sides. The gate electrode is formed in a trench formed in the active area such that it crosses the trench and is a part of a word line insulated from the active area. The silicide layer is located in the active area on either side of the gate electrode and is formed at least on the first side of the active area serving as a source and a drain region. The contact is connected to the silicide layer and connects at least a storage element.

Hereinafter, referring to the accompanying drawings, embodiments will be explained.

### First Embodiment

A saddle-fin transistor has such a structure that a fin-FET is formed at the bottom of the gate electrode of a buried-gate transistor used in a DRAM. In the gate electrode of the saddle-fin transistor, after a recess channel array transistor (RCAT) trench structure is formed, an STI part is etched in order to form a fin structure. Thereafter, a gate oxide film and polysilicon as a gate electrode are buried, thereby forming the saddle-fin transistor.

In this case, however, since the depth of the gate electrode increases, the parasitic resistance of the silicon along the depth increases. A contact in contact with the active area is composed of a barrier metal, for example, titanium (Ti), and a plug made of tungsten (W). Therefore, a titanium silicide (TiSix) layer is formed between the polysilicon layer and barrier metal. Accordingly, the titanium silicide layer is formed in an area of the inter-sidewall distance of the gate electrode×F (F being the width of the gate electrode, that is, the width of the active area). In recent years, to miniaturize elements, the inter-sidewall distance of the gate electrode and F have been made more microscopic. Therefore, the source and drain resistance of a cell transistor in a memory with the decreased area tend to increase. Consequently, it is possible to decrease an off leakage, but it is difficult to increase current and achieve high-speed operation.

Recently, a variable resistance memory, such as an MRAM, has been attracting attention as an alternative device of a DRAM. This type of device requires large current to write data and therefore a large-current drive transistor is needed. In addition, the short-channel effect, which becomes a problem in a miniaturized DRAM, must be suppressed. For the reason described above, however, it is difficult to apply a saddle-fin transistor to an MRAM or the like.

Therefore, in the first embodiment, a silicide layer is formed, for example, at one side and at the top face of an active area and a contact is formed such that it is in contact with the silicide layer, thereby decreasing the contact resistance.

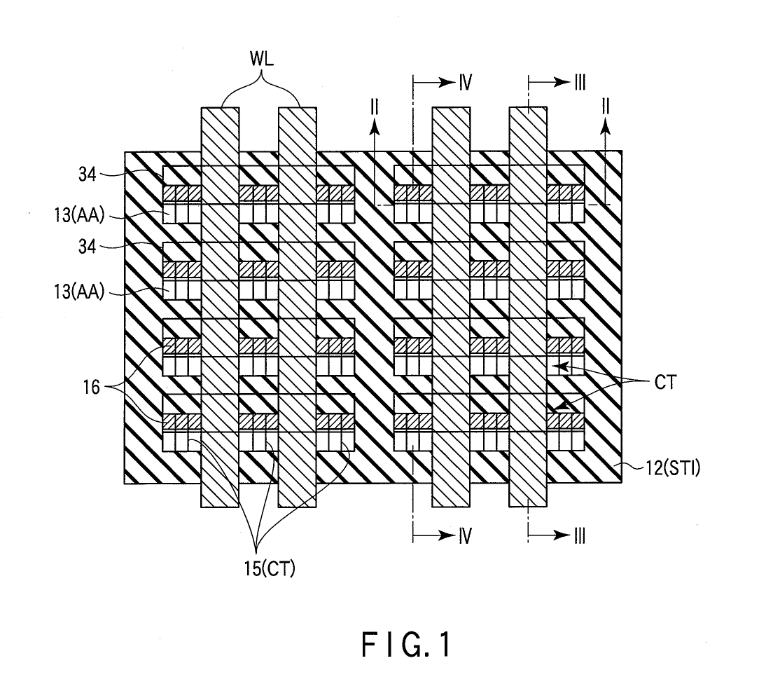

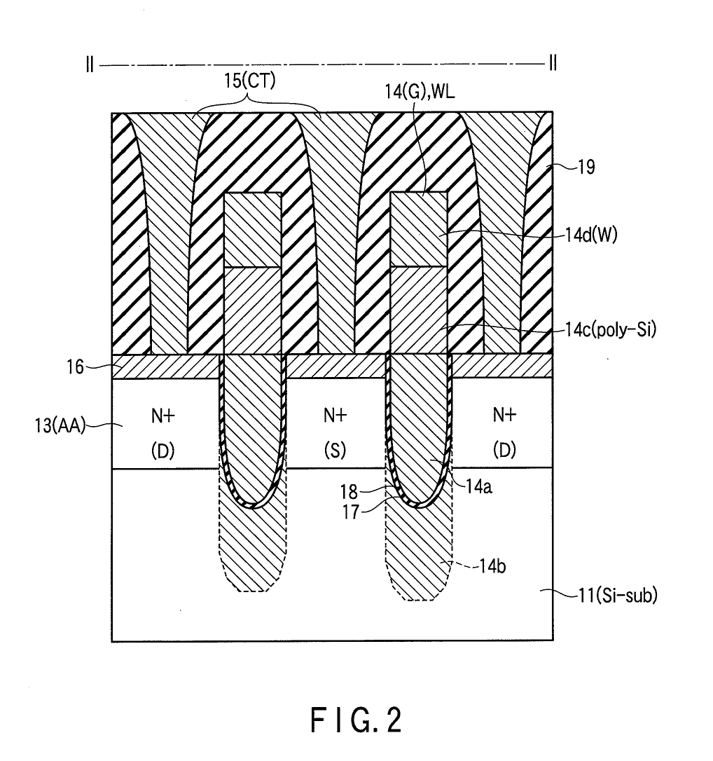

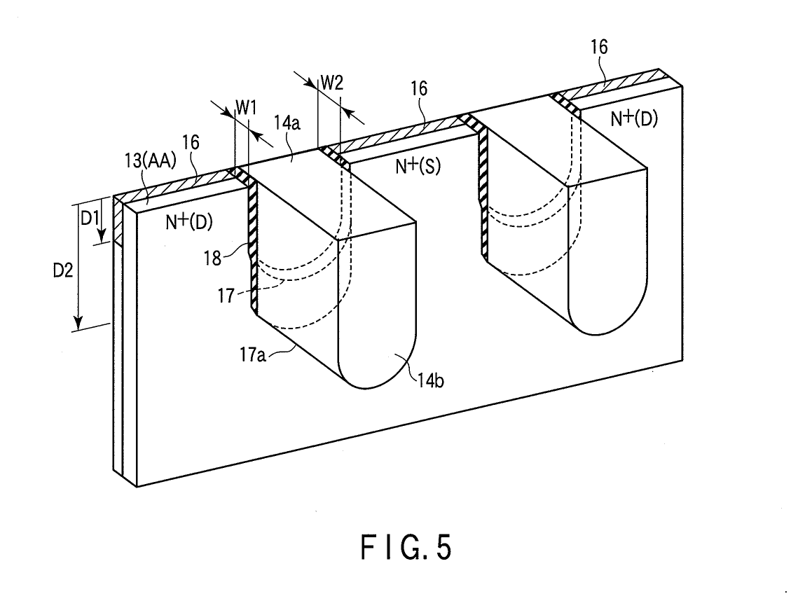

FIG. 1 is a plan view of a semiconductor memory device according to the first embodiment. FIGS. 2, 3, and 4 are sectional views taken along lines II-II, III-III, and IV-IV of FIG. 1, respectively. FIG. 5 is a perspective view of a part of FIG. 1.

As shown in FIGS. 1 to 5, a plurality of active areas (AA) 13 are formed in a silicon substrate 1. The active areas 13 are separated from one another by shallow trench isolation (STI) regions 12 as element isolation regions. Above the active areas 13, word lines WL connected to the gate electrodes 14 (G) of a plurality of cell transistors CT are formed.

As shown in FIGS. 2, 3, and 5, the gate electrode 14 is composed of a polysilicon layer 14a buried in an RCAT trench 17 formed in an active area 13, a saddle 14b, a polysilicon layer 14c, and a tungsten layer 14d. A gate insulating film 18 is formed on the inner wall of the RCAT trench 17 and on a saddle trench 17a located below the RCAT trench 17.

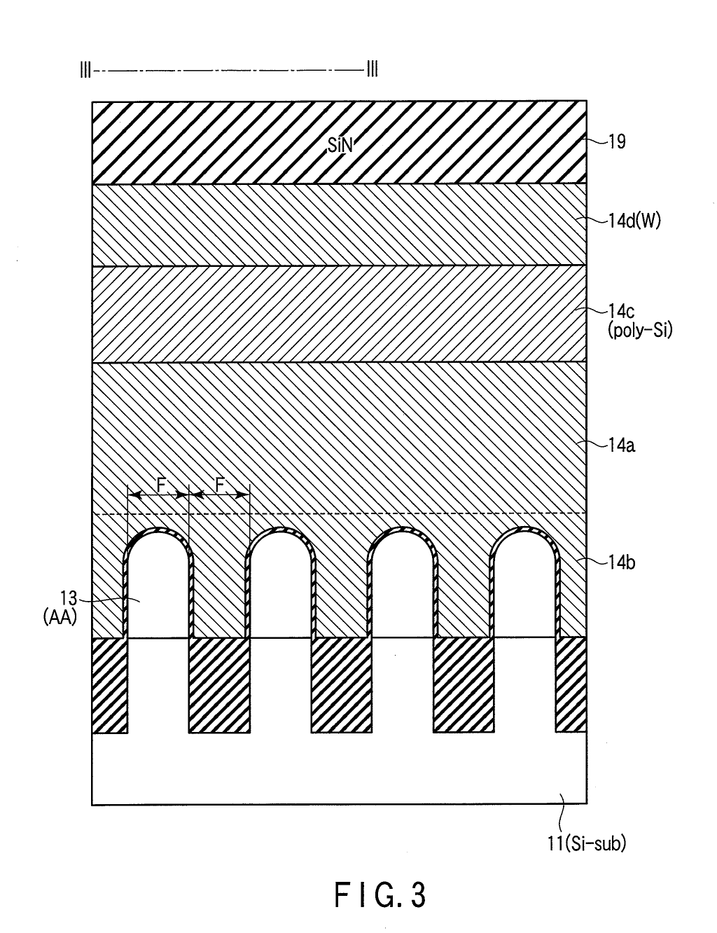

As shown in FIGS. 2 and 3, in an active area 13 located on either side of the gate electrode 14a in the RCAT trench 17, n+ diffusion layers serving as source and drain (S/D) regions are formed. That is, the source and drain (S/D) regions are formed in a direction perpendicular to a word line WL.

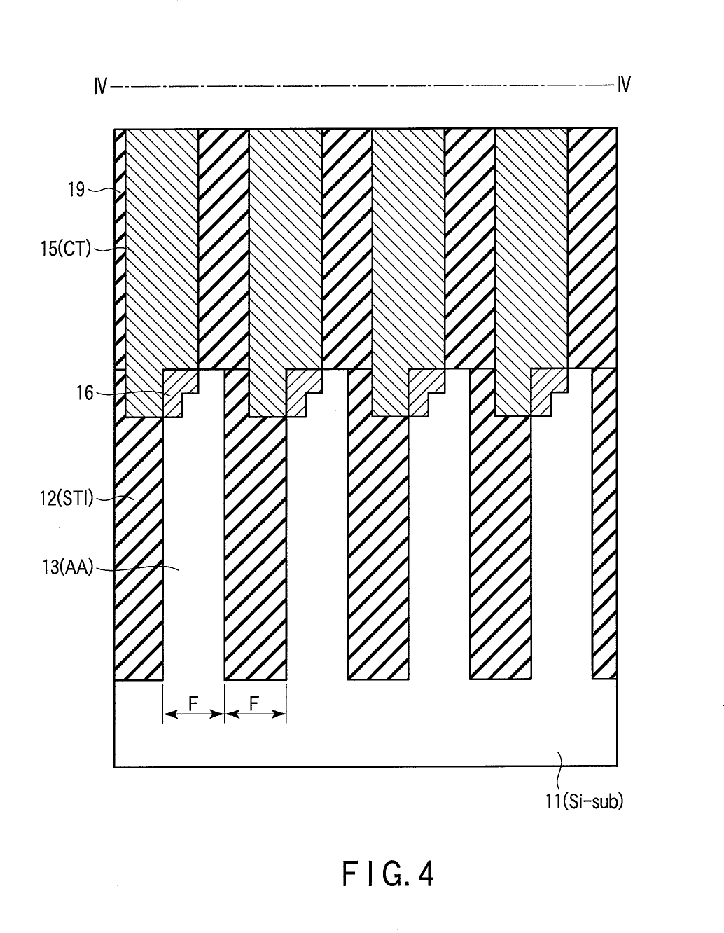

In addition, as shown in FIGS. 4 and 5, for example, at one side and at a part of the top face of the active area serving as the source and drain (S/D) regions, a silicide layer 16 is formed. Specifically, the silicide layer 16 is formed at one side and at a part of the top face of the fin-shaped active area 13 in a direction of, for example, the word line. Although the silicide layer 16 consists of at least one of, for example, cobalt, nickel, and NiPt, it is not limited to these.

As shown in FIG. 5, the depth D1 of the silicide layer 16 from the top face of the active area 13 is set to about one-third the depth D2 from the top face of the active area 13 in the RCAT trench 17. That is, the silicide layer 16 is brought closer to the channel region, thereby enabling the parasitic resistance to be reduced.

In addition, the silicide layer 16 is formed at one side and at the top face of the active area 13, causing the width W1 of the active area 13 in a direction of word line WL is set to about ½ to ⅔ of the width W2 of the gate electrode 14.

As shown in FIGS. 2 and 4, a plurality of contacts (plugs) 15 contacting the side and the top face of the silicide layer 16 constituting source and drain regions are formed. The contacts 15 are made of, for example, tungsten. The contacts 15 are formed in an insulating film 19. The insulating film 19 is, for example, a silicon nitride film.

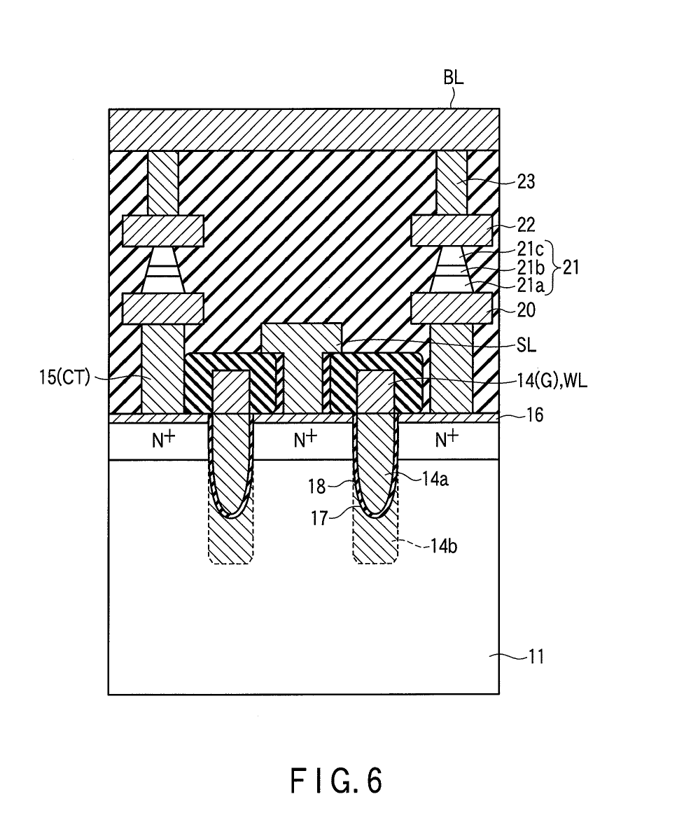

FIG. 6 shows a storage element 21. For example, a contact 15 formed on an n+ diffusion layer serving as a drain is connected to a lower electrode 20. On the lower electrode 20, a storage element 21 composed of, for example, an MRAM is formed. Specifically, the storage element 21 is composed of a storage layer 21a, an insulating layer 21b, and a reference layer 21c stacked one on top of another in that order. A top electrode 22 is formed on the reference layer 21c. The top electrode 22 is connected to a bit line BL via a contact 23. The contact 15 formed on the n+ diffusion layer as a source is connected to, for example, a source line SL. The configuration of the storage element 21 is not limited to this.

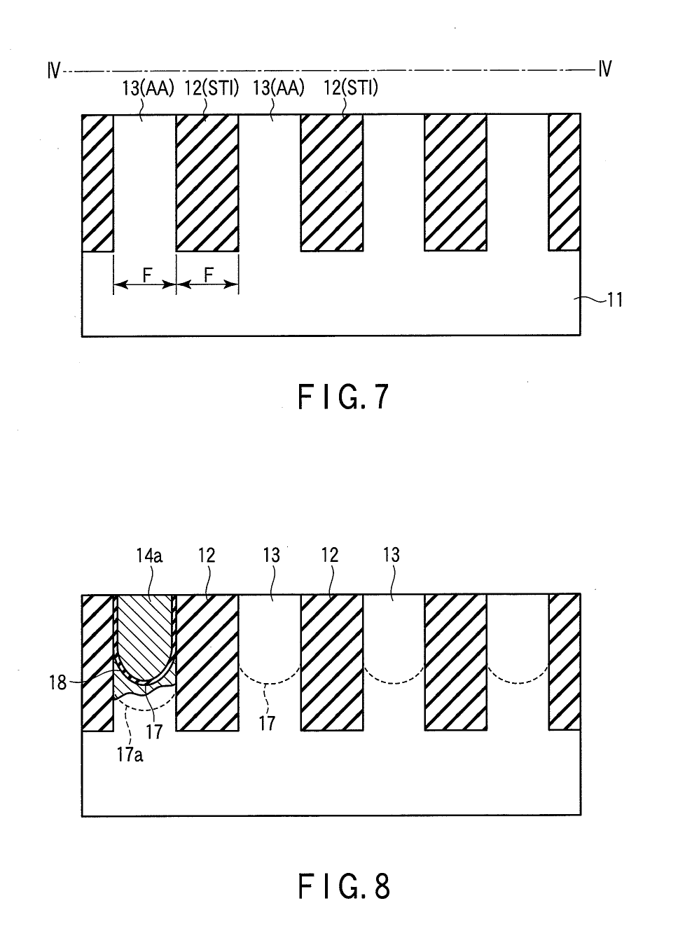

Next, a method of manufacturing a semiconductor memory device configured as described above will be explained with reference to FIGS. 7 to 14.

First, as shown in FIG. 7, a plurality of element isolation regions (STI) 12 are formed with, for example, a pitch F in the silicon substrate 11, thereby forming a plurality of active areas 13 separated by the STI. Specifically, a plurality of trenches are formed in the substrate 11. The trenches are filled with, for example, a silicon oxide film, forming element isolation regions 12.

Next, as shown in FIG. 8, each RCAT trench 17 is formed in a region where a word line is formed in each active area 13 using the reverse of a pattern for forming word lines (not shown) and, at the same time, a saddle trench 17a for forming a saddle is formed in an element isolation region 12 adjacent to each active area 13. The saddle trench 17a is set deeper than the RCAT trench 17. Thereafter, a gate insulating film 18 is formed in the RCAT trench 17 and on the inner wall of the saddle trench. Then, the RCAT trench 17 and saddle trench are filled with, for example, polysilicon layers 14a, 14b, respectively.

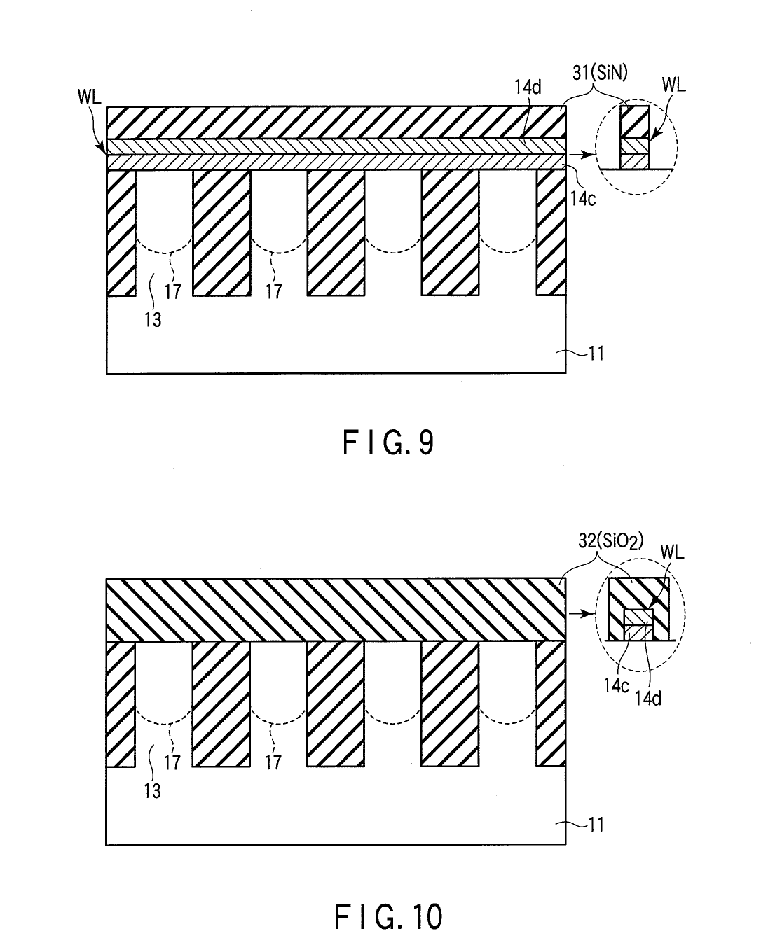

Next, as shown in FIG. 9, on the whole surface of the silicon substrate 11, for example, a polysilicon layer 14c and a tungsten layer 14d are deposited. The polysilicon layer 14c and tungsten layer 14d are etched with a pattern for forming word lines, thereby forming word lines WL as shown in FIG. 9. On the tungsten layer 14d, a hard mask 31 composed of, for example, a silicon nitride (SiN) film is formed. With this mask 31, the tungsten layer 14d and polysilicon layer 14c are etched.

Next, as shown in FIG. 10, after the silicon nitride film 31 on the word lines are removed, for example, a silicon oxide film 32 is formed on the whole surface such that it fills the space between word lines WL.

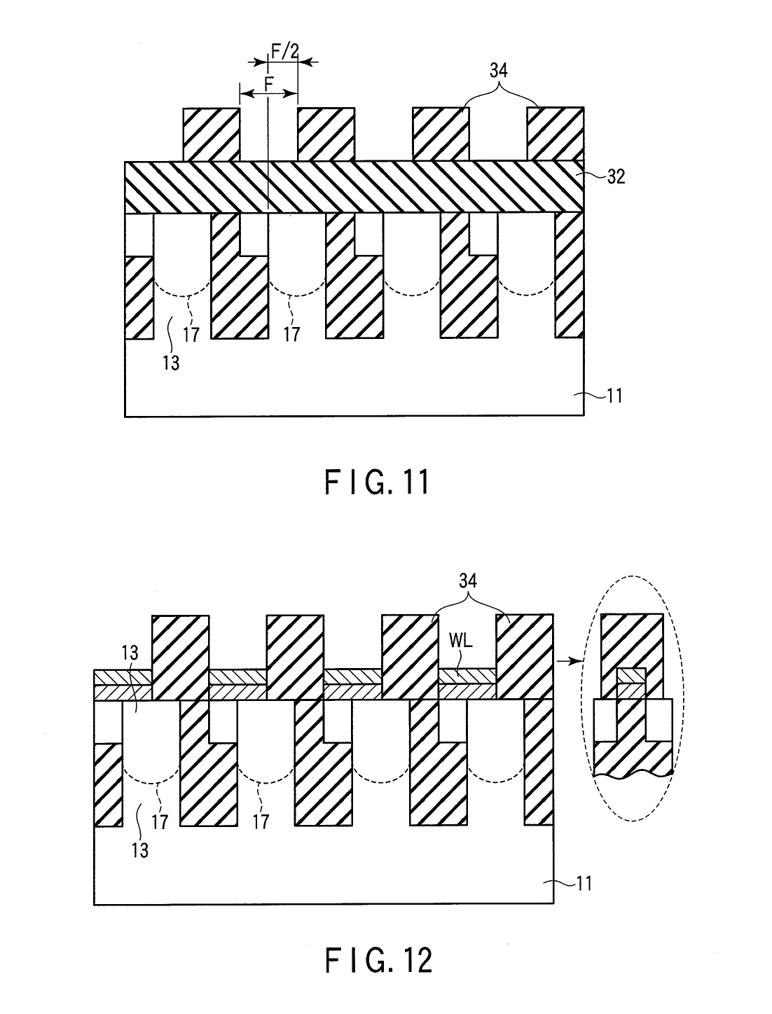

Next, as shown in FIGS. 11 and 1, a plurality of patterns 34 for forming contacts on the silicon oxide film 32 are formed by lithography. As shown in FIG. 11, the pattern 34 is formed such that it is shifted half the pitch (F/2) of the pattern of the active area 13.

Thereafter, as shown in FIG. 12, with the patterns 34, silicon forming the active areas 13 are subjected to reactive ion etching (RIE) under the condition that the selected ratio of the silicon oxide film is great. As a result, the silicon oxide film 32 between patterns 34 and the element isolation region 12 adjacent to one side of the active area 13 are removed and one side and a part of the top face of the active area 13 are exposed.

Next, after the patterns 34 are removed, for example, metal, such as cobalt or nickel, is deposited on the whole surface by sputtering or chemical vapor deposition (CVD) techniques. Thereafter, the metal is heat-treated and the unreacted metal is removed.

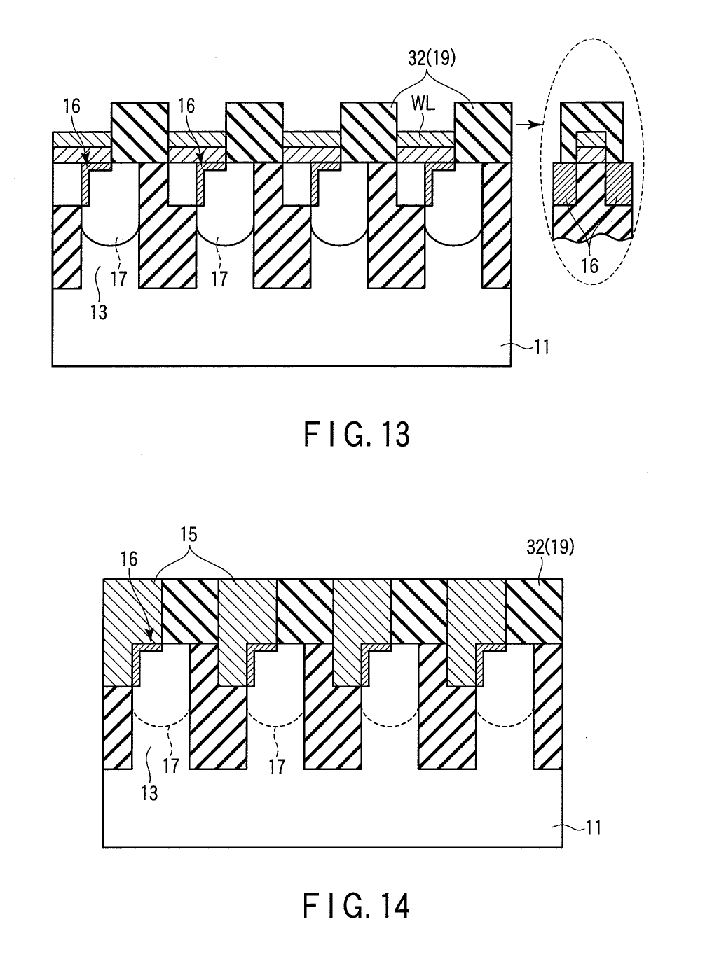

By doing this, as shown in FIG. 13, at one side and at a part of the top face of the exposed active area 13, the silicide layer 16 is formed in a self-aligning manner.

Next, barrier metal, such as tungsten, (not shown) is deposited on the whole surface by, for example, CVD techniques. With the patterns 32 as a stopper, the barrier metal is planarized by chemical mechanical polishing (CMP) techniques.

As a result, contacts 15 contacted by the silicide layer 16 are formed as shown in FIG. 14. That is, the contacts 15 are contacted by the silicide layer 16 formed at one side and at a part of the top face of the active area 13. Therefore, the contact area can be increased and therefore the contact resistance can be reduced.

In the first embodiment, the contacts 15 are formed in a self-aligning process. Therefore, an opening is also made above the gate electrode 14. However, the top of gate electrode 14 (word line WL) is not etched by selective etching, making an opening between the gate electrodes 14, above the active area 13, and above the element isolation region 12.

By the manufacturing process, a transistor with a saddle-fin structure can be formed. Thereafter, above the contacts 15, storage elements 21, source lines SL, and bit lines BL are formed, which completes a semiconductor memory device.

An n+ diffusion layer constituting a source and a drain can be formed by implanting impurity ions into the active area 13 after, for example, the word line forming process shown in FIG. 9.

With the first embodiment, a transistor with a saddle-fin structure can be formed. This allows the gate length to be increased and therefore the off leakage to be decreased. In addition, the silicide layer 16 has been formed at one side and at a part of the top face of the active area 13, thereby forming a contact 15 on the silicide layer 16. Therefore, the contact area of the active area 13 and contact 15 can be increased and the contact resistance can be decreased in a saddle-fin transistor where the area of the top face of the active area 13 as a source and a drain region is small and the contact area is small. Accordingly, a transistor with a first saddle-fin structure can not only increase current and make the operation speed faster but also be applied to such a device as an MRAM.

In addition, the depth of the silicide layer 16 formed at the top face to one side of the active area 13 is set to about one-third the depth from the top face of the active area 13 in the RCAT trench 17 and the contact face of the contact 15 and active area 13 is close to the height of the channel region. Therefore, the parasitic resistance of silicon in the depth direction can be decreased.

### Modification

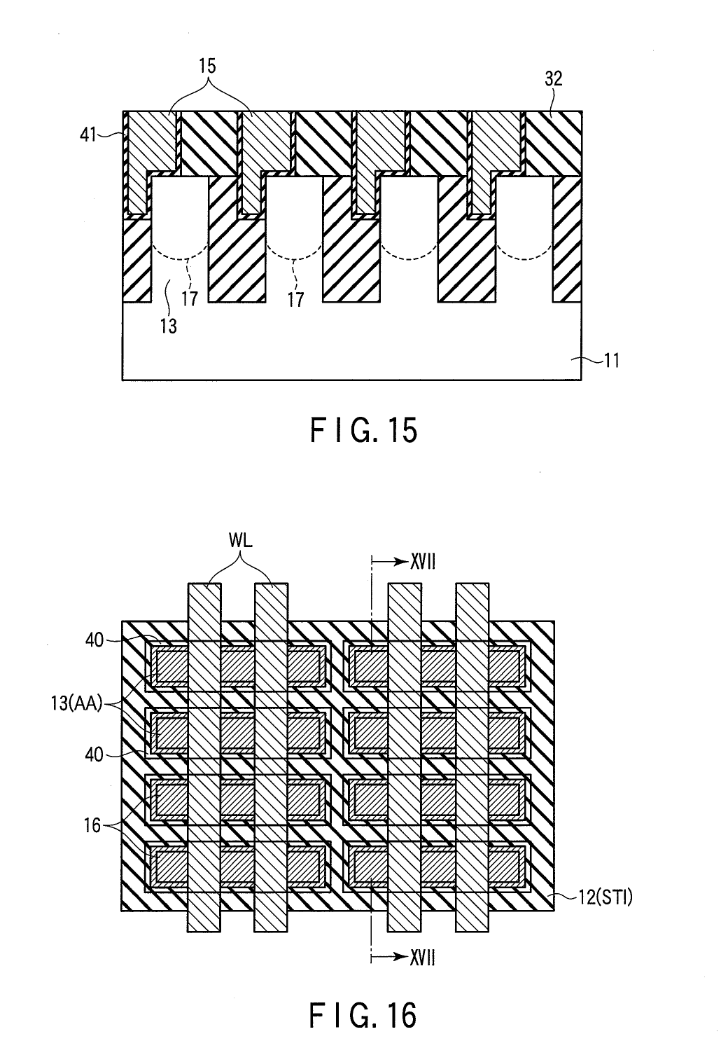

FIG. 15 shows a modification of the first embodiment.

In the first embodiment, the silicide layer 16 has been formed at one side and at a part of the top face of the active area 13. In contrast, in the modification, the contact 15 is connected to one side and a part of the top face of the active area 13 via a barrier metal 41 without forming the silicide layer 16.

Specifically, for example, as shown in FIG. 12, after the process of exposing one side and a part of the top face of the active area 13, for example, the barrier metal 41, such as titanium, is deposited without a silicide process. Thereafter, tungsten is buried in the barrier metal 41 in order to form a contact 15.

With the modification, the barrier metal 41 allows one side and a part of the top face of the active area 13 to be turned into silicide. Therefore, although the contact resistance becomes a little higher than in the first embodiment, the configuration of the modification also allows the contact area of the active area 13 and contact 15 to be increased and therefore the contact resistance to be made less than in a conventional equivalent.

### Second Embodiment

FIGS. 16 to 18 show a second embodiment. In the first embodiment, the silicide layer 16 has been formed at one side and at a part of the active area 13. In contrast, the second embodiment is such that the silicide layer 16 is formed at both sides and at the entire top face of the active area 13.

Specifically, in the first embodiment, the pattern 34 for forming a contact shown in FIG. 1 has been formed such that it is shifted half the pitch with which the active areas 13 were formed. In contrast, the second embodiment is such that an opening pattern 40 for forming a contact is formed such that it corresponds to the pitch with which the active areas 13 were formed as shown in FIG. 16 and therefore has an opening area a little larger than the area of the active area 13. Such a pattern can be formed by forming a resist pattern with the same opening as the active area 13 and making the resist pattern thinner.

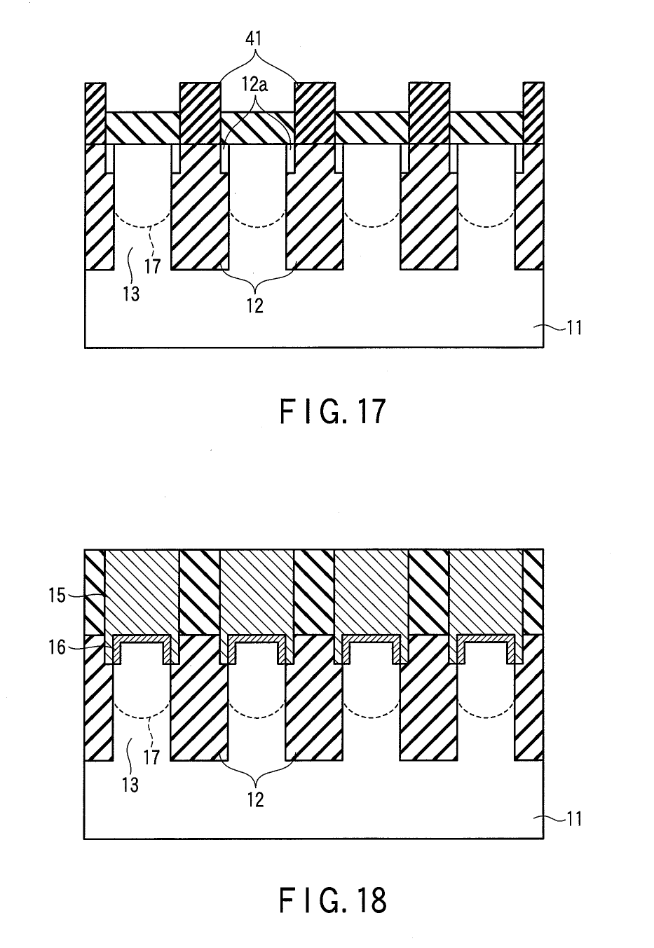

When etching is performed using the opening pattern 40, the element isolation regions 13 located around the active area 13 are removed as shown in FIG. 17. Therefore, both sides and the entire top face of the active area 13 are exposed. Thereafter, a silicide process is carried out.

As a result, a silicide layer 16 is formed at both sides and at the entire top face of the exposed active area 13 as shown in FIG. 18. Thereafter, contacts 15 are formed on the silicide layer 16.

In the second embodiment, since the active area 13 has both its sides and its entire top face, or three faces, turned into silicide, it is effective only when the width of the active area 13 can be set greater than twice the thickness of the silicide layer 16.

With the second embodiment, since the silicide layer 16 has been formed on three faces of the active area 13, the contact resistance can be decreased much more than in the first embodiment. In addition, there is no need to shift a lithographic opening pattern half the pitch, the semiconductor memory device is easy to manufacture.

### Modification

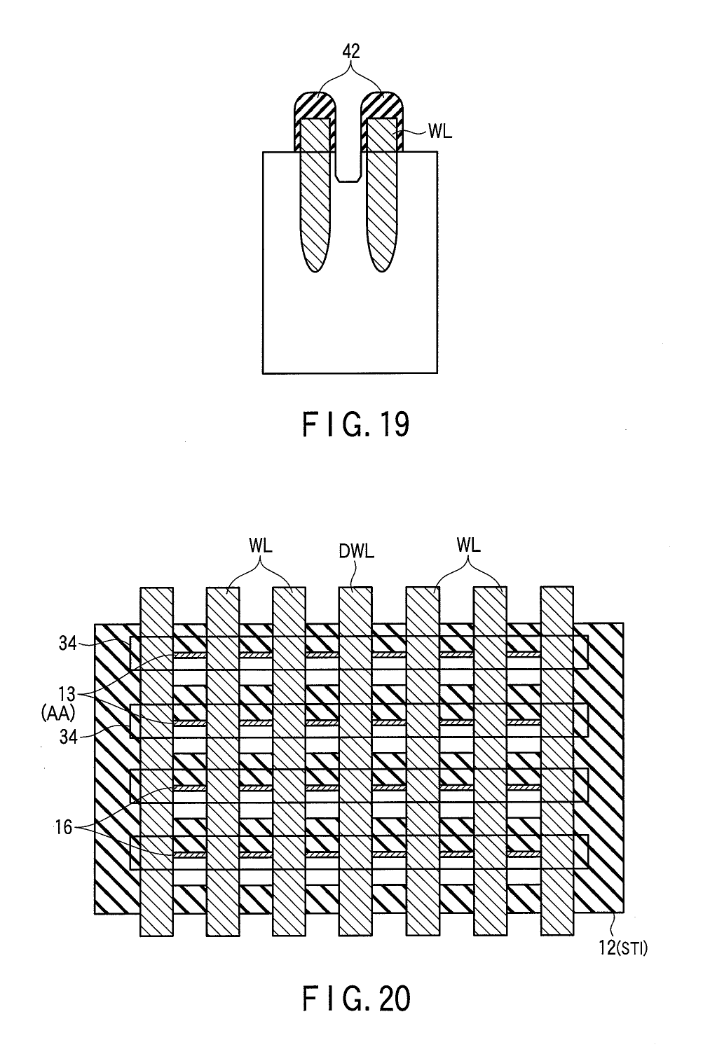

FIG. 19 shows a modification of the second embodiment. The modification is such that a silicide layer is formed at both sides and at the top face of the active area 13.

In the second embodiment, after a gate electrode (word line WL) has been formed, a space between word lines is completely filled with an insulating film as shown in FIG. 9. In contrast, the modification is such that a space between word lines is not completely filled with an insulating film and a sidewall insulating film 42 is formed such that it corresponds to the top of the element isolation region 12 as shown in FIG. 19.

Specifically, after the sidewall 42 has been formed on the sides of a word line WL as shown in FIG. 19, a plurality of patterns 40 for forming contacts are formed as shown in FIG. 16. The patterns 40 are formed such that they correspond to the pitch with which the active areas 13 are formed, and each has an opening area a little larger than the area of the active area 13. With the patterns 40 and sidewall insulating film 42 as a mask, the element isolation region 12 is etched so that a recessed part 12a may be formed on either side of the active area 13. Therefore, as shown in FIG. 17, both sides and the top face of the active area 13 are exposed as shown in FIG. 17.

Thereafter, as shown in FIG. 18, a silicide layer 16 is formed on both sides and the top face of the exposed active area 13. Then, contacts 15 are formed on the silicide layer 16. The contact 15 is formed such that it contacts the silicide layer 16 formed on both sides and the top face of the active area 13. Therefore, the contact area of the silicide layer 16 and contact 15 can be made larger than in the first embodiment. Accordingly, the contact resistance can be made less than in the first embodiment.

In the second embodiment, the contacts 15 may be formed after the barrier metal has been formed without forming the silicide layer 16 as in the modification of the first embodiment.

Furthermore, as shown in FIG. 9, after word lines WL have been formed, a sidewall insulating film 42 is formed as shown in FIG. 19 without the process of filling a space between word lines WL with an insulating film as shown in FIG. 10. Thereafter, the entire face of the element isolation region 12 is etched in order to make the height of the top face of the element isolation region 12 less than the height of the top face of the active area 13. As a result, both sides and the top face of the active area 13 are exposed. Thereafter, a silicide layer is formed on both exposed sides and the exposed top face of the active area 13. Even with such a manufacturing method, it is possible to achieve a similar configuration to that of the modification.

### Third Embodiment

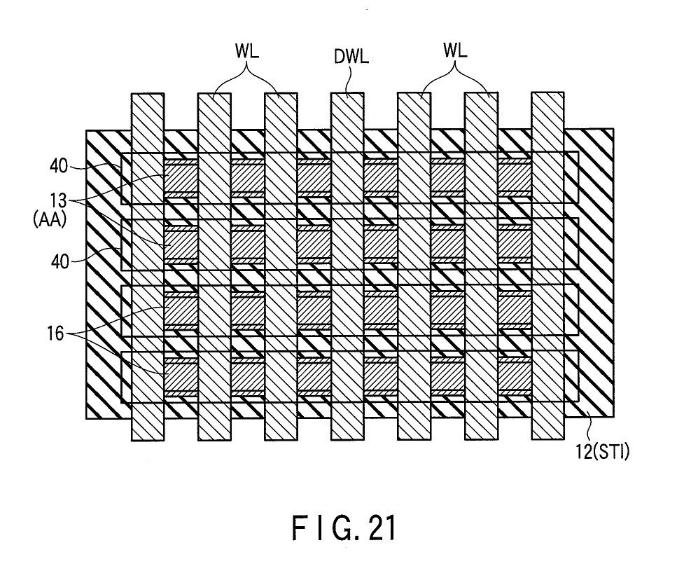

FIGS. 20 and 21 show a third embodiment. In the first and second embodiments, the active area 13 has been formed such that it has an island shape. In contrast, the third embodiment is such that active areas 13 and element isolation regions 12 form a line-and-space (L/S) pattern for three or more word lines WL as shown in FIGS. 20 and 21.

In the first and second embodiments, a space wider than the pitch with which word lines were formed has been formed between word line pairs. In contrast, in the third embodiment, since an L/S pattern of word lines and insulating films is formed on the space, there is no space such as the first and second embodiments.

In FIG. 20, an opening pattern 34 for a contact is shifted half the pitch with which active areas 13 were formed as in the first embodiment. Therefore, a silicide layer is formed at one side and at a part of the top face of the active area 13 as in the first embodiment.

In FIG. 21, an opening pattern 40 for a contact is caused to correspond to the pitch with which active areas 13 were formed as in the second embodiment. Therefore, a silicide layer is formed on both sides and the entire top face of the active area 13 as in the second embodiment.

In the first and second embodiments, four active areas 13 including a word line pair have been separated by element isolation regions 12.

In contrast, the third embodiment is such that four active areas 13 including a word line pair have been separated by a dummy gate provided between word line pairs. Specifically, the potential of a dummy word line DWL connected to the dummy gate is set to, for example, zero (ground potential), turning the transistor off. Therefore, one word line pair and the other word line pair are electrically separated from each other.

With the third embodiment, the active areas 13 and word lines WL can be formed with an L/S pattern with high regularity. Therefore, the third embodiment has the advantage of facilitating lithography.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a fin-shaped active area which is provided in a semiconductor substrate and which has a first side, a second side parallel to the first side, and a top face connecting the first and second sides;
a gate electrode which is formed in a trench formed in the active area such that the gate electrode crosses the trench and which is a part of a word line insulated from the active area;
a silicide layer which is located in the active area on either side of the gate electrode and which is formed at least on the first side of the active area serving as a source and a drain region; and
a contact which is connected to the silicide layer and which connects at least a storage element.

2. The semiconductor memory device according to claim 1, wherein the width of the active area is equal to or less than two-thirds the gate width of the gate electrode.

3. The semiconductor memory device according to claim 1, wherein the depth of the silicide layer is set to one-third the depth of the trench.

4. The semiconductor memory device according to claim 1, wherein the contact connected to the silicide layer and active area is shifted half a pitch in a direction of the word line when the width of the active area is set as a pitch.

5. The semiconductor memory device according to claim 1, wherein the silicide layer is formed at the first and second sides and at the top face of the active area.

6. The semiconductor memory device according to claim 5, further comprising a contact configured to connect the silicide layer formed at the first and second sides and at the top face of the active area.

7. The semiconductor memory device according to claim 4, wherein the contact has its underside constituted of at least one of cobalt, nickel, and NiPt.

8. The semiconductor memory device according to claim 6, wherein the contact has its underside constituted of at least one of cobalt, nickel, and NiPt.

9. The semiconductor memory device according to claim 1, further comprising an element isolation region adjacent to the active area, the active area and element isolation region being formed by a line-shaped pattern for three or more word lines.

10. The semiconductor memory device according to claim 9, further comprising a dummy gate which is provided in four active areas including a plurality of word line pairs and specifically between the word line pairs.

11. The semiconductor memory device according to claim 10, wherein the dummy gate is set to the ground potential and the word line pairs are electrically separated from one another.

12. A method of manufacturing a semiconductor memory device, the method comprising:
forming a fin-shaped active area which is separated by an element isolation region in a semiconductor substrate and which has a first side, a second side parallel to the first side, and a top face connecting the first and second sides;
forming a first trench in the active area and further forming a second trench deeper than the first trench in the element isolation region adjacent to the active area;
forming a first gate electrode in the first and second tranches such that the first gate electrode crosses the active area, the first gate electrode being a part of a word line insulated from the active area;
forming a silicide layer at least at the first side of the active area on either side of the gate electrode; and
forming a contact for connecting at least a storage element to the silicide layer formed in the active area on either side of the gate electrode.

13. The method according to claim 12, wherein the width of the active area is equal to or less than two-thirds the gate width of the gate electrode.

14. The method according to claim 12, wherein the depth of the silicide layer is set to one-third the depth of the first trench.

15. The method according to claim 12, wherein the contact configured to connect the silicide layer and active area is shifted half a pitch in a direction of the word line when the width of the active area is set as a pitch.

16. The method according to claim 12, wherein the silicide layer is formed at the first and second sides and at the top face of the active area.

17. The method according to claim 12, wherein the contact has its underside constituted of cobalt.

18. The method according to claim 15, wherein the contact has its underside constituted of cobalt.
